(19) United States
(12) Patent Application Publication
(10) Pub. No.: US 2014/0042645 A1
(43) Pub. Date: Feb. 13, 2014

(54) RESIN SHEET FOR SEALING ELECTRONIC COMPONENT, RESIN-SEALED TYPE SEMICONDUCTOR DEVICE AND METHOD FOR PRODUCING RESIN-SEALED TYPE SEMICONDUCTOR DEVICE

(71) Applicant: Nitto Denko Corporation, Osaka (JP)

(72) Inventors: Yusaku Shimizu, Ibaraki-shi (JP); Takeshi Matsumura, Ibaraki-shi (JP); Eiji Toyoda, Ibaraki-shi (JP); Tsuyoshi Torinari, Ibaraki-shi (JP)

(73) Assignee: NITTO DENKO CORPORATION, Osaka (JP)

(21) Appl. No.: 13/960,694

(22) Filed: Aug. 6, 2013

(30) Foreign Application Priority Data
Aug. 8, 2012 (JP) 2012-176146

(51) Int. Cl. H01L 23/28

(52) U.S. Cl. CPC H01L 23/28
USPC 257/787; 428/220; 523/466; 156/60

(57) ABSTRACT

An electronic-component-sealing resin sheet capable of restraining the warp amount of a package obtained by use of the sheet, a resin-sealed type semiconductor device high in reliability, and a method for producing the device are provided. The present invention relates to a resin sheet for sealing an electronic component, wherein after the resin sheet is hot-pressed onto an iron nickel alloy plate containing 42% by weight of nickel and having a shape 90 mm square and a thickness of 0.15 mm to give a thickness 0.2 mm and the resultant hot-pressed unit is cured at 150° C., the unit exhibits a warp amount of 5 mm or less.

### BACKGROUND OF THE INVENTION

1. Field of the Invention

The present invention relates to a resin sheet for sealing an electronic component, a resin-sealed type semiconductor device, and a process for producing a resin-sealed type semiconductor device.

2. Description of the Related Art

Conventionally, in the production of a semiconductor device, semiconductor chips are mounted onto a substrate that may be of various types, such as a lead frame or a circuit substrate, and subsequently the semiconductor chips and other electronic components are sealed with a resin to be covered therewith. In the thus-produced resin-sealed type semiconductor device, stress is generated by a difference in shrinkage amount between the sealing resin, and the semiconductor chips or the substrate, which may be of various types. This stress causes a problem that the package is warped.

For example, JP-A-10-226769 describes a film-form adhesive having an adhesive layer containing an inorganic filler in a specified proportion. JP-A-2001-49220 describes a composition for a film-form adhesive that contains silica in a specified proportion. JP-A-2004-346186 describes a sheet-form adhesive material obtained by supplying, independently onto a release sheet, resin components mixed preliminarily with each other and filler components mixed preliminarily with each other, and further covering the upper of these components with a release sheet. However, with respect to each of these sheet-form adhesive materials, sufficient investigations have not been made into restraining the warp amount of the resultant package by making the material low in linear expansion coefficient.

### SUMMARY OF THE INVENTION

In light of the above-mentioned problems, the present invention has been made. An object thereof is to provide an electronic-component-sealing resin sheet capable of restraining the warp amount of a package obtained by use of the sheet, a resin-sealed type semiconductor device high in reliability, and a method for producing the device.

In order to solve the problems in the prior art, the inventors have made eager investigations to pay attention to a fact that an iron nickel alloy plate containing nickel in a proportion of 42 by weight (42 alloy) is close in linear expansion coefficient to silicon wafers or silicon chips. The inventors have then found that when a resin sheet on this iron nickel alloy plate is cured, and subsequently the warp amount of the resultant unit is set to a specified value or less, a resin-sealed type semiconductor device high in reliability is thereby produced. In this manner, the invention has been achieved.

Accordingly, the present invention relates to a resin sheet for sealing an electronic component, wherein after the resin sheet is hot-pressed onto an iron nickel alloy plate containing 42% by weight of nickel and having a shape 90 mm square and a thickness of 0.15 mm to give a thickness 0.2 mm and the resultant hot-pressed unit is cured at 150° C., the unit exhibits a warp amount of 5 mm or less.

Regarding the electronic-component-sealing resin sheet of the invention, after the resin sheet is cured on the specified iron nickel alloy plate, the warp amount of the resultant unit is 5 mm or less. This warp amount is small. For this reason, when a silicon wafer or a silicon chip is sealed with the resin sheet, the resultant sealed product is also small in warp amount. As a result, a resin-sealed type semiconductor device high in reliability can be obtained.

The content by percentage of silica in the whole of the sheet is preferably from 85% by weight to 93% by weight. According to this structure, the resin sheet can be decreased in linear expansion coefficient so that the unit obtained after the resin is cured can be satisfactorily restrained in warp amount.

The electronic-component-sealing resin sheet is preferably produced by kneading extrusion.

In any resin sheet produced by painting in such a manner of being filled with silica in a high proportion, filler precipitation is easily caused in surfaces of the resin sheet so that the sheet is deteriorated in wettability or the sheet is not satisfactorily laminated onto another member. However, the structure described just above this paragraph makes it possible to yield an electronic-component-sealing resin sheet which is good in silica-dispersing performance and can be satisfactorily laminated onto a different member.

Moreover, the silica highly-filled resin easily becomes high in viscosity so that the viscosity thereof is not easily controlled. It is therefore difficult to shape the resin into a sheet form by painting. However, the structure described just above this paragraph makes it possible to shape the resin as raw material easily into a sheet form since the resin sheet is produced by kneading extrusion. The sheet can be rendered a homogeneous sheet having no voids (air bubbles) or other defects. When a resin sheet is produced by painting, the particle diameter of silica usable therein tends to be restrained. However, the structure described just above this paragraph makes it possible to use silica regardless the particle diameter thereof.

Regarding the electronic-component-sealing resin sheet, it is preferred that after the resin sheet is hot-pressed onto a glass fabric based epoxy resin having a shape 90 mm square and a thickness of 0.3 mm to give a thickness 0.2 mm and the resultant hot-pressed unit is cured at 150° C., the unit exhibits a warp amount of 4 mm or less.

According to this structure, after the resin sheet is cured on the specified glass fabric based epoxy resin, the warp amount of the resultant unit is a small value of 4 mm or less. As a result, a resin-sealed type semiconductor device high in reliability can be obtained.

After the resin sheet of the invention is cured, the linear expansion coefficient thereof is preferably 10 ppm/K or less at temperatures lower than the glass transition temperature of the cured resin sheet. This manner makes it possible to restrain the warp amount satisfactorily.

After the resin sheet of the invention is cured, the linear expansion coefficient thereof is preferably 50 ppm/K or less at temperatures equal to or higher than the glass transition temperature of the cured resin sheet. This manner makes it possible to restrain the warp amount satisfactorily.

After the resin sheet of the invention is cured, the glass transition temperature thereof is preferably 100° C. or higher. In this way, the warp amount after the sheet is cured can be restrained in a wide temperature range (particularly, at temperatures up to 100° C.).

After the resin sheet of the invention is cured at 150° C. for 1 hour, the tensile modulus of the cured resin sheet is preferably 2 GPa or more at room temperature. When the tensile modulus is 2 GPa or more, a resin-sealed type semiconductor device can be obtained which is excellent in scratch resistance and high in reliability. The thickness of the resin sheet of the invention is preferably from 0.1 mm to 0.7 mm.

The invention also relates to a resin-sealed type semiconductor device obtained by use of the above-mentioned electronic-component-sealing resin sheet.

The invention also relates to a method for producing a resin-sealed type semiconductor device, comprising the step of using the resin sheet to seal an electronic component.

### BRIEF DESCRIPTION OF THE DRAWINGS

FIG. 1 is a view illustrating a resin sheet used to measure the warp amount defined in the invention;

FIG. 2 is a view illustrating a test plate used to measure the warp amount; and

FIG. 3 is a view illustrating a test piece.

### DETAILED DESCRIPTION OF THE PREFERRED EMBODIMENTS

The resin sheet of the invention is a sheet wherein after the resin sheet is hot-pressed onto an iron nickel alloy plate containing 42% by weight of nickel and having a shape 90 mm square and a thickness of 0.15 mm to give a thickness 0.2 mm and the resultant hot-pressed unit is cured at 150° C., the unit exhibits a warp amount of 5 mm or less.

The resin sheet of the invention preferably contains an epoxy resin and a phenol resin. This manner makes it possible for the sheet to achieve a good thermosetting property.

The epoxy resin is not particularly limited, and examples thereof include triphenyl methane type epoxy resin, cresol novolak type epoxy resin, biphenyl type epoxy resin, modified bisphenol A type epoxy resin, bisphenol A type epoxy resin, bisphenol F type epoxy resin, modified bisphenol F type epoxy resin, dicyclopentadiene type epoxy resin, phenol novolak type epoxy resin, phenoxy resin, and other various epoxy resins. These epoxy resins may be used alone or in combination of two or more thereof.

The epoxy resin is preferably an epoxy resin which is in a solid form at room temperature, and has an epoxy equivalent of 150 to 250 and a softening point or melting point of 50° C. to 130° C. in order to certainly attain a desired toughness after curing and reactivity. Particularly preferred are triphenylmethane type epoxy resin, cresol novolak type epoxy resin, and biphenyl type epoxy resin from the viewpoint of the reliability.

The phenolic resin is not particularly limited as far as the resin causes a curing reaction with the epoxy resin. Examples thereof include phenol novolak resin, phenol aralkyl resin, biphenyl aralkyl resin, dicyclopentadiene type phenolic resin, cresol novolak resin, and resol resin. These phenolic resins may be used alone or in combination of two or more thereof.

The phenolic resin is preferably a resin having a hydroxyl equivalent of 70 to 250 and a softening point of 50° C. to 110° C. from the viewpoint of the reactivity thereof with the epoxy resin. The phenolic resin is in particular preferably phenol novolak resin because the resin is high in curing reactivity. Moreover, from the viewpoint of the reliability, the phenolic resin is a low-hygroscopicity phenolic resin such as phenol aralkyl resin, or biphenyl aralkyl resin can be preferably used.

Regarding the blend ratio between the epoxy resin and the phenolic resin, the entire amount of the hydroxyl groups in the phenolic resin is preferably from 0.7 to 1.5 equivalents, more preferably 0.9 to 1.2 equivalents per equivalent of epoxy groups in the epoxy resin from the viewpoint of the curing reactivity therebetween.

The total content by percentage of the epoxy resin and the phenol resin is preferably from 50% by weight to 85% by weight of all of these resin components and any other optional resin component. The total content by percentage is more preferably 70% or more by weight. When the content by percentage is 50% or more by weight, the resin sheet can achieve a good adhesive strength to a semiconductor chip, a lead frame, a glass fabric based epoxy resin or the like.

The resin sheet of the invention may contain a thermoplastic resin. When the sheet contains the thermoplastic resin, the sheet can achieve a good softness and flexibility.

Examples of the thermoplastic resin include natural rubber, butyl rubber, isoprene rubber, chloroprene rubber, ethylene/vinyl acetate copolymer, ethylene/acrylic acid copolymer, ethylene/acrylic ester copolymer, polybutadiene resin, polycarbonate resin, thermoplastic polyimide resin, polyamide resins such as 6-nylon and 6,6-nylon, phenoxy resin, acrylic resin, saturated polyester resins such as PET and PBT, polyamideimide resin, and fluorine-containing resin. Other examples thereof include styrene/isobutylene/styrene block copolymer. These thermoplastic resins may be used alone or in combination of two or more thereof. Among these examples, styrene/isobutylene/styrene block copolymer is particularly preferred from the viewpoint of humidity resistance.

The content by percentage of the thermoplastic resin in the entire resin components is preferably 30% or less by weight. When the content by percentage of the thermoplastic resin in the entire resin components is 30% or less by weight, the resin sheet can achieve a good adhesive strength to a semiconductor chip, a lead frame, a glass fabric based epoxy resin or the like. The lower limit of the content by percentage is not particularly limited, and is, for example, 15% by weight.

It is preferred to use silica (silica powder) in the resin sheet of the invention since a cured product of the sheet can be decreased in linear expansion coefficient. It is more preferred to use, among silica powder species, a fused silica powder species. Examples of the fused silica powder include spherical fused silica powder, and crushed fused silica powder. From the viewpoint of fluidity, spherical fused silica powder is particularly preferred. The average particle diameter of the spherical fused silica powder is preferably from 10 μm to 30 μm, in particular preferably from 15 μm to 25 μm from the viewpoint of the height of an ordinary electric component to which the resin sheet is applied, and the thickness of the resin sheet to be shaped.

The average particle diameter may be determined, for example, by measurement using a laser diffraction scattering type particle size distribution measuring device on a sample extracted arbitrarily from a population of the particles.

The silica content by percentage in the whole of the resin sheet is preferably from 85% by weight to 93% by weight, more preferably from 86% by weight to 92% by weight, even more preferably from 87% by weight to 90% by weight. When the silica content by percentage is 85% or more by weight, a resin composition low in linear expansion coefficient and excellent in reliability can be obtained. When the silica content bypercentage is 93% or less by weight, a resin composition excellent in fluidity can be obtained.

The resin sheet of the invention preferably contains a curing promoter. The curing promoter is not particularly limited as far as the promoter is an agent for promoting the curing. The curing promoter is preferably an organic phosphorous compound, such as triphenylphosphine or tetraphenylphosphonium tetraphenyl borate, or an imidazole compound from the viewpoint of curing-promotion performance and storability.

The content of the curing promoter is preferably from 0.1 parts to 5 parts by weight for 100 parts by weight of the resin components.

Other Components:

The resin sheet of the invention preferably contains a flame retardant component. This component makes it possible that when the electric component short-circuits or generates heat to ignite, flammability is decreased. The flame retardant component may be various metal hydroxides such as aluminum hydroxide, magnesium hydroxide, iron hydroxide, calcium hydroxide, tin hydroxide, or any complexed metal hydroxide. Preferred is aluminum hydroxide or magnesium hydroxide, and particularly preferred is aluminum hydroxide from the viewpoint of costs and an advantage that the metal hydroxide can exhibit flame retardancy in a relatively small addition amount thereof.

Besides the above-mentioned individual components, the resin sheet of the invention may appropriately contain other additives, such as carbon black or any other pigment, and a silane coupling agent, if necessary.

The resin sheet of the invention may be produced by an ordinary method. Preferably, the resin sheet is produced by kneading extrusion. This method makes it possible to yield a resin sheet which is good in silica-dispersing performance, and can be satisfactorily laminated onto a different member. This method also makes it possible to shape the raw material of the individual components easily into the form of a sheet, and make the sheet homogeneous so as not to have voids (air bubbles) or other defects. Silica may be used in the resin sheet regardless of the particle diameter thereof.

The method for the production by kneading extrusion is, for example, a method of using a known kneading machine, such as a mixing roll, a pressurized kneader or an extruder, to melt and knead the above-mentioned individual components, thereby preparing a kneaded product, and then extruding the resultant kneaded product to be shaped into a sheet form. Conditions for the kneading are as follows: the kneading temperature is preferably a temperature equal to or higher than the respective softening points of the individual components, and is, for example, from 30° C. to 150° C. When the thermosetting property of the epoxy resin is considered, the temperature is preferably from 40° C. to 140° C., more preferably from 60° C. to 120° C. The period is, for example, from 1 to 30 minutes and is preferably from 5 to 15 minutes. Through this process, the kneaded product can be prepared.

The resultant kneaded product is shaped by extrusion, whereby the resin sheet can be yielded. Specifically, after the melting and kneading, the kneaded product is extruded in the state of being kept at the high temperature state without being cooled, whereby the resin sheet can be formed. The method for the extrusion is not particularly limited, and examples thereof include T-die extrusion, roll rolling, roll kneading, co-extrusion, and calender forming methods. The extruding temperature is preferably equal to or higher than the respective softening points of the individual components. When the thermosetting property and the formability of the epoxy resin are considered, the temperature is, for example, from 40° C. to 150° C., preferably from 50° C. to 140° C., even more preferably from 70° C. to 120° C. By the above-mentioned operations, the resin sheet of the invention can be formed.

Regarding the resin sheet of the invention, after the resin sheet is hot-pressed onto an iron nickel alloy plate containing 42% by weight of nickel and having a shape 90 mm square and a thickness of 0.15 mm to give a thickness 0.2 mm and the resultant hot-pressed unit is cured at 150° C., the unit exhibits a warp amount of 5 mm or less. The warp amount is small. Thus, the resin is close in linear expansion coefficient to semiconductor chips so that a resin-sealed type semiconductor device high in reliability can be obtained. The warp amount is preferably 4 mm or less.

The warp amount defined in the invention is measured by a method described in Examples.

When the thickness of the resin sheet is less than 0.2 mm, the method for adjusting the thickness to 0.2 mm by the hot-pressing may be a method of laminating a plurality of resin sheets onto each other to form a laminate having a thickness of 0.2 mm or more, and then hot-pressing the laminate to adjust the thickness to 0.2 mm.

Regarding the resin sheet of the invention, it is preferred that after the resin sheet is hot-pressed onto a glass fabric based epoxy resin having a shape 90 mm square and a thickness of 0.3 mm to give a thickness 0.2 mm and the resultant hot-pressed unit is cured at 150° C., the unit exhibits a warp amount of 4 mm or less. When the warp amount of the unit after the sheet is cured on the glass fabric based epoxy resin is within this range, a resin-sealed type semiconductor device higher in reliability can be obtained. The warp amount defined in the invention is measurable by the method described in Examples. When the thickness of the resin sheet is less than 0.2 mm, the method for adjusting the thickness to 0.2 mm by the hot-pressing may be a method of laminating a plurality of resin sheets onto each other to form a laminate having a thickness of 0.2 mm or more, and then hot-pressing the laminate to adjust the thickness to 0.2 mm.

After the resin sheet of the invention is cured, the glass transition temperature thereof is preferably 100° C. or higher, more preferably 120° C. or higher. In this way, the warp amount after the sheet is cured can be restrained in a wide temperature range.

The glass transition temperature is measurable by a method described in Examples.

After the resin sheet of the invention is cured, the linear expansion coefficient thereof is preferably 10 ppm/K or less at temperatures lower than the glass transition temperature of the cured resin sheet. When the linear expansion coefficient is 10 ppm/K or less, the coefficient is small so that the warp amount can be satisfactorily restrained.

After the resin sheet of the invention is cured, the linear expansion coefficient thereof is preferably 50 ppm/K or less at temperatures equal to or higher than the glass transition temperature of the cured resin sheet. When the liner expansion coefficient is 50 ppm/K or less, the coefficient is small so that the warp amount can be satisfactorily restrained.

The linear expansion coefficient is measurable by a method described in Examples.

After the resin sheet of the invention is cured at 150° C. for 1 hour, the tensile modulus of the cured resin sheet is preferably 2 GPa or more at room temperature. When the tensile modulus is 2 GPa or more, a resin-sealed type semiconductor device can be obtained which is excellent in scratch resistance and high in reliability.

In the present specification, the term “room temperature” refers to 25° C. The tensile modulus is measurable by a method described in Examples.

The thickness of the resin sheet of the invention is not particularly limited, and is preferably from 0.1 mm to 0.7 mm. The thickness of the resin sheet is more preferably 0.2 mm or more. The thickness of the resin sheet is also more preferably 0.5 mm or less. When the thickness is within this range, the resin sheet makes it possible to seal an electronic component satisfactorily. By making the resin sheet thin, the amount of heat generated therefrom can be decreased so that the resin sheet does not undergo curing shrinkage easily. As a result thereof, the package warp amount can be decreased to yield a resin-sealed type semiconductor device higher in reliability.

The thus yielded resin sheet may be used in the form of a single-layered structure. Alternatively, this resin sheet, and one or more resin sheets equivalent thereto may be used in the form of a multi-layered structure in which these resin sheets, the number of which is two or more, are laminated onto each other.

The resin sheet of the invention is used to seal an electronic component, such as a semiconductor wafer, a semiconductor chip, a condenser or a resistor. Specifically, the resin sheet is suitable for sealing a semiconductor wafer or a semiconductor chip, and is particularly suitable for sealing a silicon wafer or a silicon chip.

The method for the sealing is not particularly limited, and may be any sealing method known in the prior art. The method is, for example, a method of putting the resin sheet in an uncured state onto a substrate to cover an electronic component on the substrate, and then curing the resin sheet thermally to seal the component. The substrate is, for example, a glass fabric based epoxy resin.

A resin-sealed type semiconductor device yielded by such a method is small in warp amount after the substrate on which the electronic component is mounted is sealed with the resin sheet and then the resin sheet is cured. Thus, the device is high in reliability.

### EXAMPLES

The present invention is explained in detail with reference to the examples below. However, the present invention is not limited to the following examples, and includes variations of these examples as long as their purpose is not frustrated. “Part (s) ” in each example is on a weight basis as long as there is no special notation to indicate otherwise.

The following describes each component used in the examples: Epoxy resin: YSLV-80XY (bisphenol F type epoxy resin) manufactured by Nippon Steel Chemical Co., Ltd.
Phenol resin: MEH7851SS (phenol biphenylene) manufactured by Meiwa Plastic Industries, Ltd.
Elastomer: SIBSTER 072T (polystyrene/polyisobutylene based resin) manufactured by Kaneka Corp.
Spherical fused silica: FB-9454FC (54-μm-cut fused spherical silica; average particle diameter: 20 μm) manufactured by Denki Kagaku Kogyo K.K.
Silane coupling agent: KBN-403 (3-glycidoxypropyltrimethoxysilane) manufactured by Shin-Etsu Chemical Co., Ltd.
Carbon black: #20 manufactured by Mitsubishi Chemical Corp.
Flame retardant: FP-100 (phosphonitrilic acid phenyl ester) manufactured by Fushimi Pharmaceutical Co., Ltd.
Catalyst: 2PHZ-PW (imidazole based catalyst) manufactured by Shikoku Chemicals Corp.

Each of the test plate species used in the examples is as follows:
42 Alloy plates: 42 Alloy YEF 42 plates manufactured by Hitachi Ltd. (iron nickel alloy plates each containing 42% by weight of nickel and having a shape 90 mm square and a thickness of 0.15 mm) (hardness: 210 Hy, tensile strength: 640 N/mm², and average linear expansion coefficient at 30° C. to 200° C.: 4.3×10⁶/° C.); and
FR-4 plates: Glass Epoxy Multi (FR-4) R-1766 plates manufactured by Panasonic Corp. (glass fabric based epoxy resin plates each having a shape 90 mm square and a thickness of 0.3 mm)

### <Production of Each Resin Sheet>

In accordance with each blend ratio shown in Table 1, individual components were mixed with each other and kneaded at 60° C. to 120° C. for 10 minutes, using a biaxial kneader. In this way, each kneaded product was prepared. Next, the kneaded product was extruded and shaped to yield a resin sheet.

The resultant resin sheet was used and evaluated as described below. The results are shown in Table 1.

### <Measurement of Warp Amount>

With reference to FIGS. 1 to 3, a description is made about a method for measuring the warp amount of each of the resin sheets.

FIG. 1 is a view illustrating a resin sheet 1 used to measure the warp amount.

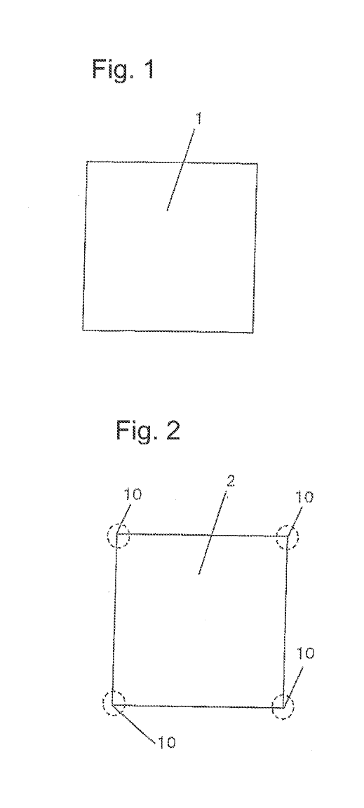

FIG. 2 is a view illustrating a test plate 2 used to measure the warp amount.

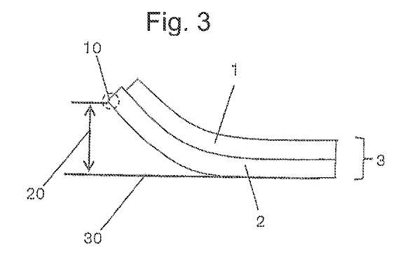

FIG. 3 is a view illustrating a test piece 3.

### Production of Test Piece 3:

The resin sheet 1, which had a shape 90 mm square and a thickness of 0.25 mm, was hot-pressed onto the test plate 2 (the 42 alloy or FR-4 plate) to give a thickness of 0.2 mm.

The hot-pressing was performed in a temperature range (90° C.) permitting the viscosity of the resin to be 5000 Pa-s or less in an atmosphere having a reduced pressure of 20 Torr, using an immediate vacuum laminating machine (parallel-flat-plate press) [VS008-1515, manufactured by Mikado Tachnos Co., Ltd.].

After the hot-pressing, a portion of the resin that was pushed out from the test plate 2 was taken away with a cutter, and then the resin sheet 1 was cured for 1 hour, using a 150° C.-hot-wind circulating drier (STH-120, manufactured by Espec Corp.). After the curing, the unit was cooled at room temperature (25° C.) for 1 hour to yield the test piece 3.

Measurement of Warp Amount:

As illustrated in FIG. 3, the test piece was put on a horizontal desk, and (in the state that four corners 10 of the test piece 3 floated) a ruler was used to measure a perpendicular distance 20 from the desk upper surface 30 to each of the corners 10 of the test piece 3. About each of the fourth corners 10, which the test piece 3 had, the distance 20 was measured, and the average of the resultant values was calculated. The calculated average of the distances 20 was defined as the warp amount.

The viscosity of the resin was measured with a viscoelasticity measurement instrument ARES manufactured by Seiko Instruments Inc. (under the following measuring conditions: a measurement temperature range from 40° C. to 175° C., a temperature-raising rate of 10° C./min and a frequency of 1 Hz).

### <Measurement of Linear Expansion Coefficient and Glass Transition Temperature>

Each of the resin sheets, 4.9 mm wide, 25 mm long and 0.2 mm thick, was cured at 150° C. for 1 hour. The cured resin sheet was set to a device, TMA8310, manufactured by Rigaku Corp., and then the linear expansion coefficient and the glass transition temperature thereof were measured at a tensile load of 4.9 mN and a temperature-raising rate of 10° C./min.

### <Measurement of Tensile Modulus>

Each of the resin sheets, 10 mm wide, 30 mm long and 0.4 mm thick, was cured at 150° C. for 1 hour. The cured resin sheet was set to a device, RSA-2, manufactured by TA Instruments Co., and then the tensile modulus thereof was measured at a frequency of 1 Hz and a temperature-raising rate of 10° C./min.

TABLE 1

| | | | | | Comparative | Comparative |
|---|---|---|---|---|---|---|
| | | Example 1 | Example 2 | Example 3 | Example 1 | Example 2 |
| Ratio between | Epoxy resin | 3.4 | 4.0 | 3.7 | 7.1 | 4.0 |
| blend amounts | Phenol resin | 3.6 | 4.2 | 3.9 | 7.5 | 4.2 |
| (parts by | Elastomer | 3.0 | 3.5 | 3.3 | 6.3 | 3.5 |
| weight) | Spherical fused silica | 87.9 | 85.9 | 86.9 | 75.0 | 85.9 |
| | Silane coupling agent | 0.1 | 0.1 | 0.1 | 0.1 | 0.1 |
| | Carbon black | 0.1 | 0.1 | 0.1 | 0.1 | 0.1 |
| | (Organic) flame retardant | 1.8 | 2.1 | 1.9 | 3.7 | 2.1 |
| | Catalyst | 0.1 | 0.1 | 0.1 | 0.2 | 0.1 |
| Total | | 100 | 100 | 100 | 100 | 100 |
| Production method | | Kneading | Kneading | Kneading | Kneading | Solvent |
| | | extrusion | extrusion | extrusion | extrusion | painting |
| Evaluation | Average(mm) of warp amounts | 4 | 4.4 | 4.4 | 6 | Unable to be |
| | of 42-alloy-used test piece | | | | | produced |
| | Average (mm) of warp amount | 2 | 3 | 2.5 | 5 | |
| | of FR-4-used test piece | | | | | |
| | Linear expansion | 7 | 10 | 8 | 25 | |
| | coefficient (ppm/K) at | | | | | |
| | temperatures lower than | | | | | |
| | glass transition | | | | | |
| | temperature | | | | | |
| | Linear expansion | 40 | 46 | 43 | 88 | |
| | coefficient (ppm/K) at | | | | | |
| | temperatures equal to or | | | | | |
| | higher than glass transition | | | | | |
| | temperature | | | | | |
| | Glass transition | 105 | 105 | 105 | 105 | |
| | temperature (° C.) | | | | | |
| | Tensile modulus (GPa) | 4 | 2 | 3 | 2 | |

As shown in Table 1, the resin sheet obtained in each of Examples 1 to 3 was a sheet wherein the average of the warp amounts of the 42-alloy-used test piece was 5 mm or less.

In each of Examples 1 to 3, the resin sheet 1 having an original thickness of 0.25 mm was used. It was verified that even when a resin sheet having an original thickness of 1 mm was used, the same results were obtained as when the resin sheets each having an original thickness of 0.25 mm were used about the average of the warp amounts of their 42-alloy-used test piece and the average of the warp amounts of their FR-4-used test piece. From this result, it has been made evident that as far as resin sheets each having an original thickness of 0.2 mm or more are used, the same results are obtained about the following amounts regardless of the respective original thicknesses thereof: the average of the warp amounts of their 42-alloy-used test piece and the average of the warp amounts of their FR-4-used test piece.

### DESCRIPTION OF THE REFERENCE NUMERALS

1 Resin sheet
2 Test plate
3 Test piece
10 Corner parts
20 Distance between corner parts 10 and upper surface 30 of desk
30 Upper surface of desk

What is claimed is:

1. An electronic-component-sealing resin sheet, wherein after the electronic-component-sealing resin sheet is hot-pressed onto an iron nickel alloy plate containing 42% by weight of nickel and having a shape 90 mm square and a thickness of 0.15 mm to give a thickness 0.2 mm and a resultant hot-pressed unit is cured at 150° C., the hot-pressed unit exhibits a warp amount of 5 mm or less.

2. The electronic-component-sealing resin sheet according to claim 1, wherein a content by percentage of silica in the electronic-component-sealing resin sheet is from 85% by weight to 93% by weight.

3. The electronic-component-sealing resin sheet according to claim 1, which is produced by kneading extrusion.

4. The electronic-component-sealing resin sheet according to claim 1, wherein after the electronic-component-sealing resin sheet is hot-pressed onto a glass fabric based epoxy resin having a shape 90 mm square and a thickness of 0.3 mm to give a thickness 0.2 mm and the resultant hot-pressed unit is cured at 150° C., the hot-pressed unit exhibits a warp amount of 4 mm or less.

5. The electronic-component-sealing resin sheet according to claim 1, which has, after curing, a linear expansion coefficient of 10 ppm/K or less at temperatures lower than a glass transition temperature of the cured electronic-component-sealing resin sheet.

6. The electronic-component-sealing resin sheet according to claim 1, which has, after curing, a linear expansion coefficient of 50 ppm/K or less at temperatures equal to or higher than a glass transition temperature of the cured electronic-component-sealing resin sheet.

7. The electronic-component-sealing resin sheet according to claim 1, wherein after the sheet is cured, a glass transition temperature of the cured resin sheet is 100° C. or higher.

8. The electronic-component-sealing resin sheet according to claim 1, wherein after the electronic-component-sealing resin sheet is cured at 150° C. for 1 hour, a tensile modulus of the cured electronic-component-sealing resin sheet is 2 GPa or more at room temperature.

9. The electronic-component-sealing resin sheet according to claim 1, which has a thickness of 0.1 mm to 0.7 mm.

10. A resin-sealed type semiconductor device, obtained by use of the electronic-component-sealing resin sheet recited in claim 1.

11. A method for producing a resin-sealed type semiconductor device, comprising the step of using the electronic-component-sealing resin sheet recited in claim 1 to seal an electronic component.
